(19) United States
(12) Patent Application Publication
(10) Pub. No.: US 2015/0039813 A1
(43) Pub. Date: Feb. 5, 2015

(54) NAND Interface Capacity Extender Device For Extending Solid State Drives Capacity, Performance, And Reliability

(71) Applicant: Greenliant LLC, Santa Clara, CA (US)

(72) Inventors: Chuan-Ding Arthur Hsu, San Jose, CA (US); Siamak Arya, Cupertino, CA (US); Yung-Chin Chen, Saratoga, CA (US); Lei Zhang, Beijing (CN); Dongsheng Xing, Fremont, CA (US)

(21) Appl. No.: 14/445,047

(22) Filed: Jul. 28, 2014

Related U.S. Application Data
(60) Provisional application No. 61/862,466, filed on Aug. 5, 2013.

(51) Int. Cl. G11C 16/10

(52) U.S. Cl. CPC G11C 16/107
USPC 711/103

(57) ABSTRACT

A system and method for a solid state drive comprising a system controller and one or more extender devices coupled to the system controller is disclosed, where each extender device is coupled to a plurality of NAND storage devices and each NAND storage device comprising a plurality of NAND flash memory cells.

### CROSS REFERENCE TO RELATED APPLICATION

This patent application claims priority to U.S. Provisional Application No. 61/862,466, filed on Aug. 5, 2013, and titled “NAND INTERFACE CAPACITY EXTENDER DEVICE FOR EXTENDING SSD CAPACITY, PERFORMANCE, AND RELIABILITY,” which is incorporated herein by reference in its entirety.

### FIELD OF THE INVENTION

The present invention relates to NAND Solid State Drives.

### BACKGROUND OF THE INVENTION

The Solid State Drive (SSD) has delivered many advantages over the Hard Disk Drive (HDD) which include higher performance, lower power consumption, and smaller foot print. SSDs can pack many small NAND devices (where a NAND device can comprise one or more arrays or semiconductor dies of NAND flash memory cells) into a small package with high read/write performance where HDDs must use many drives to achieve the same performance Therefore, a single SSD can replace many HDDs for the same performance level. However, in order to achieve the high capacity requirements of many applications, many SSDs must be used even though the performance may be sufficient. This is because an SSD is usually composed of a controller with multiple NAND buses, and each NAND bus supports a limited number of NAND devices. The number of such buses is limited per controller due to limitation on the practical number of pins a controller can afford.

SSD performance is achieved by operating many NAND devices in parallel and overlapping the flash array read or write operation with data transfer. If this is fully achieved, the read or write operation will be transfer bound, hence achieving maximum possible performance Due to relatively short flash array read time, the number of NAND devices required per NAND bus to achieve transfer bound status is relatively small. For example, for 4 KB transfers on and 200 MT/s bus (5 ns per Byte) for a flash array read time of 100 μs, it only requires 5 NAND devices to match a 100 μs transfer time with 100 μs array read time and saturate the NAND bus. However, with increasing flash array read time, and for shorter than 4 KB read operations such as 512 byte reads, the number of required NAND devices will increase beyond the currently practical number.

For write performance, writing a full page of 16 KB with a NAND array write time of 1600 μs, it will require 20 NAND devices to be active all at the same time on the same NAND bus; 1600 μs/(16*5 ns)=20.

The number of NAND devices on a NAND bus is limited due to multiple factors, some of which are stated below:

Loading: the higher the number of NAND devices on the bus, the higher the capacitance which will affect the frequency the bus can run on. Also, both the controller and the NAND device must have enough drive strength to drive these signals.

Signal Integrity: higher bus frequency and complex bus topology will cause signal integrity problems limiting the number of NAND devices on the bus.

Packaging: since the number of NAND devices per package is limited, multiple NAND device packages must be used. This also increases impedance and capacitance due to long board traces causing signal integrity and drive strength problems.

Unfortunately, due to the limitation on the number of NAND devices per NAND bus as implemented in prior art products, SSD capacity and performance are limited below the full potential of the SSD's controller. The current limit on the number of NAND devices on a bus in prior art products is 8. Therefore, in order to increase capacity or performance, one has to resort to the use of multiple SSDs increasing cost and foot print.

Even though the drive strength of the controller signals can be increased as needed, commercial NAND devices have limited drive strength to keep power consumption under control and cannot drive a large number of devices on one bus. Therefore, increasing the number of NAND devices on a NAND bus beyond 8 is difficult, and beyond 16 impractical today. Hence the full capability of the SSD cannot be utilized.

### BRIEF SUMMARY OF THE INVENTION

In order to increase the number of NANDs per NAND bus on a controller, a NAND Interface Capacity Extender (NICE) device has been developed. NICE is an intermediary circuit that interacts with the controller to receive commands and data, and relays the commands to a limited number of NAND devices and other NICE devices, and returns data and control information to the controller.

The number of NAND devices per NAND bus is increased by either connecting a number of NICE devices on a bus to the controller in parallel, or by connecting NICE devices serially where each NICE device, in addition to connecting to the NAND devices, connects to another NICE device. The NICE device can be configured to comply with any standard or proprietary NAND interface as well as any standard or proprietary interface to the controller.

Since in either the parallel or the serial connection topology, NICE devices are connected to the controller or each other via standard NAND bus interface or a proprietary interface, the drive strength and signal integrity issues can be resolved between the controller and the NICE devices without requiring a change to the NAND device.

Any number of NICE devices can be utilized in order to increase the capacity of the SSD. And, with increase in the number of NAND devices per controller NAND bus, write performance can also be improved.

### BRIEF DESCRIPTION OF THE DRAWINGS

FIG. 1 shows an example of a serial mode connection of NICE devices.

FIG. 2 shows an example of a parallel mode connection of NICE devices.

FIG. 3 shows an example of a mixed mode connection of NICE devices.

FIG. 4 shows an example of a limited loading serial connection of NICE devices.

FIG. 5 shows an example of an all in one connection of NICE devices.

FIG. 6 shows an example of a serial mode connection of NICE devices without non-shared signals.

FIG. 7 shows an example of a parallel mode connection of NICE devices without non-shared signals.

FIG. 8 shows an example of a mixed mode connection of NICE devices without non-shared signals.

FIG. 9 shows an example of a serial mode connection of NICE devices with an additional spare NICE device with 2 spare NAND devices.

FIG. 10 shows an example of converting logical NAND device numbers to physical NAND device numbers on the fly.

### DETAILED DESCRIPTION OF THE INVENTION

Since the number of NAND devices that can be connected to a NAND bus are limited, e.g. currently 8 NAND devices, an extender device, NICE, is provided as an intermediary between the controller and the NAND devices. When multiple NICE devices are used together, the number of NAND devices that share a bus is multiplied.

In the embodiments that follow, NICE receives commands and data from the controller, and transfers them to the selected NAND device. It also receives data and status information from NAND devices and transfers them to the controller.

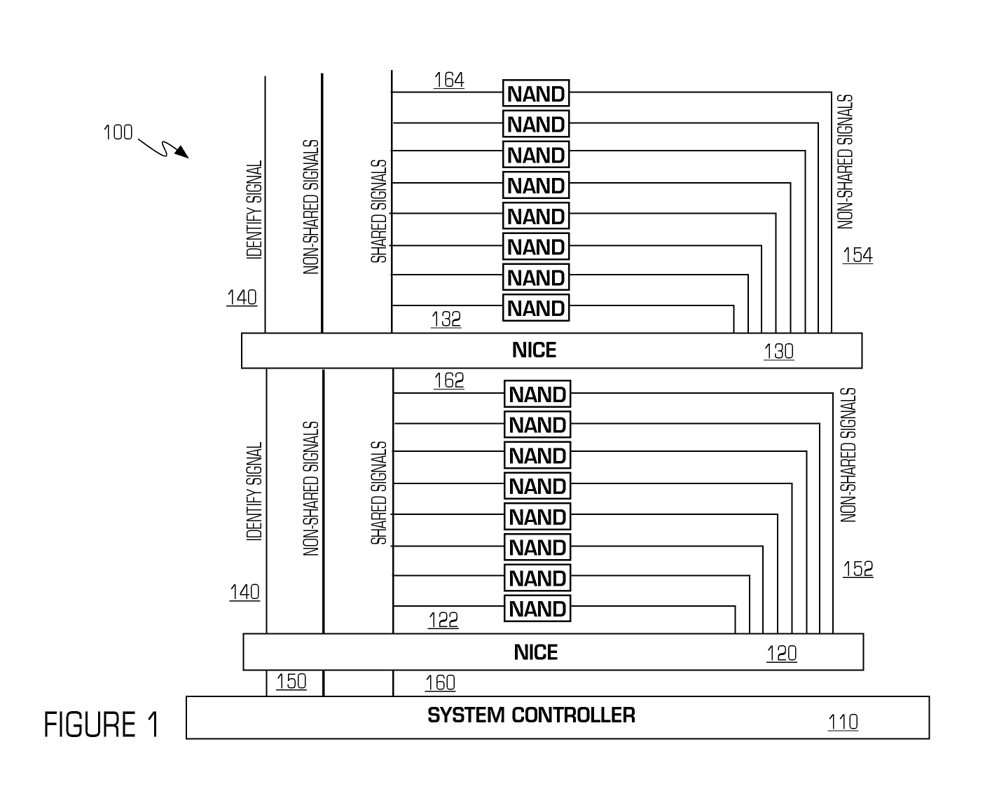

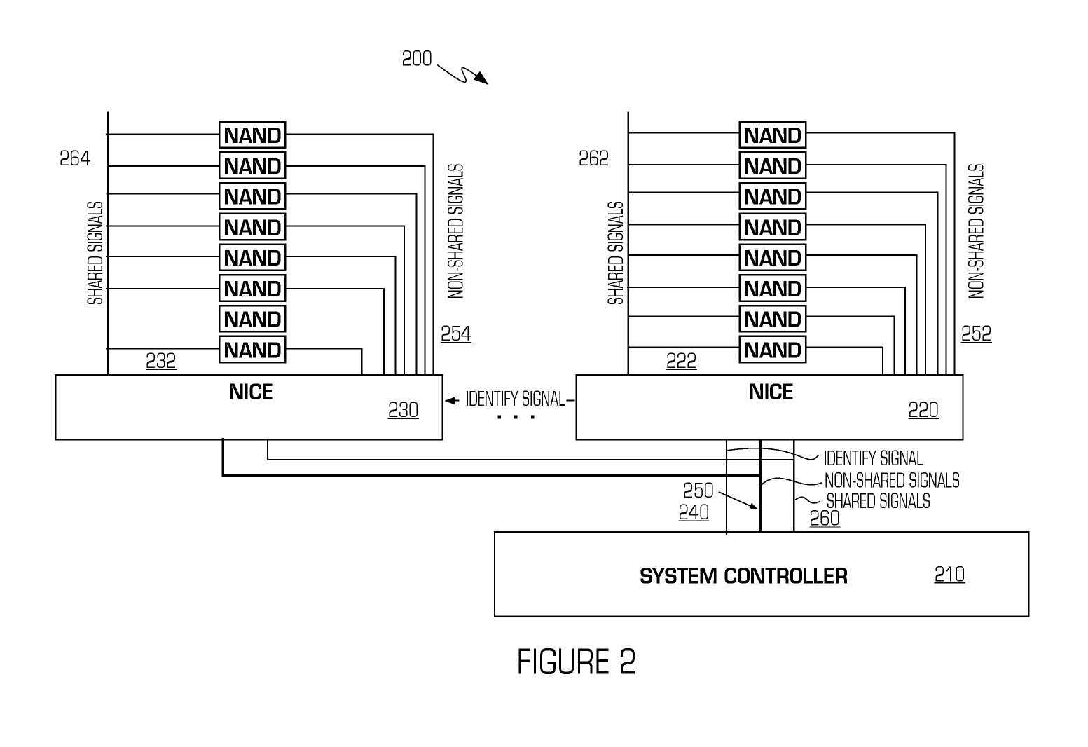

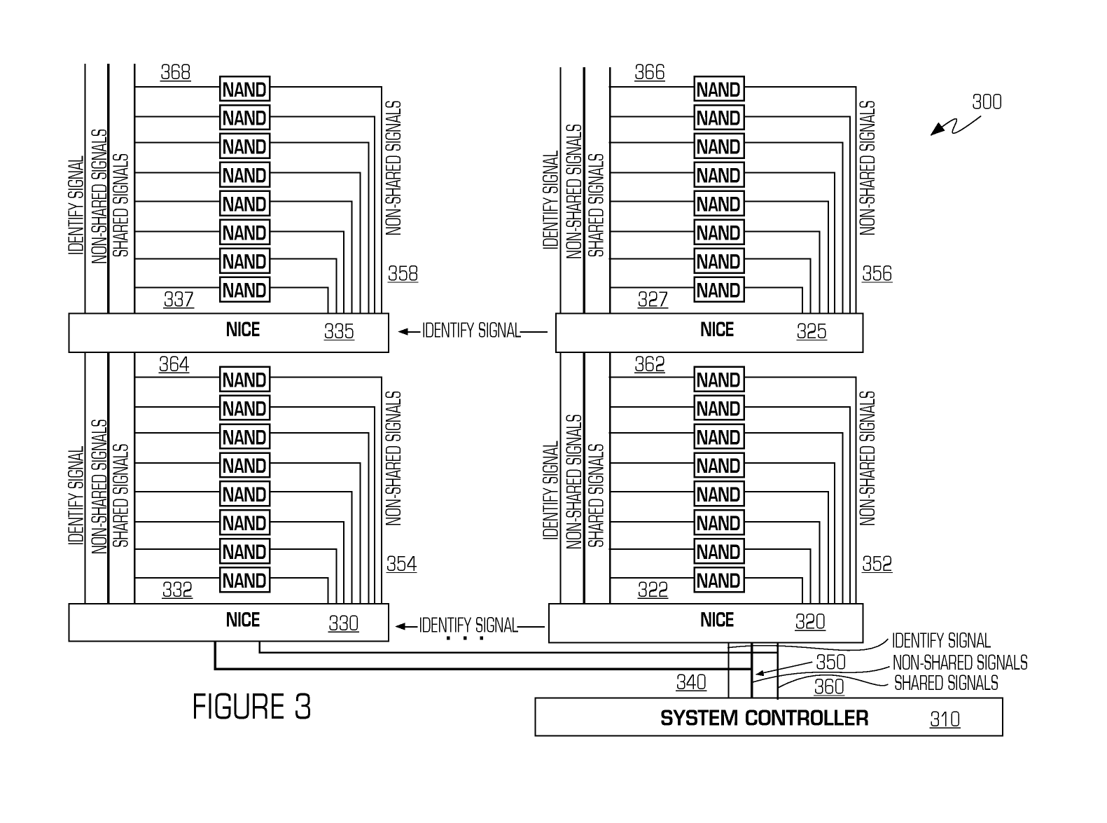

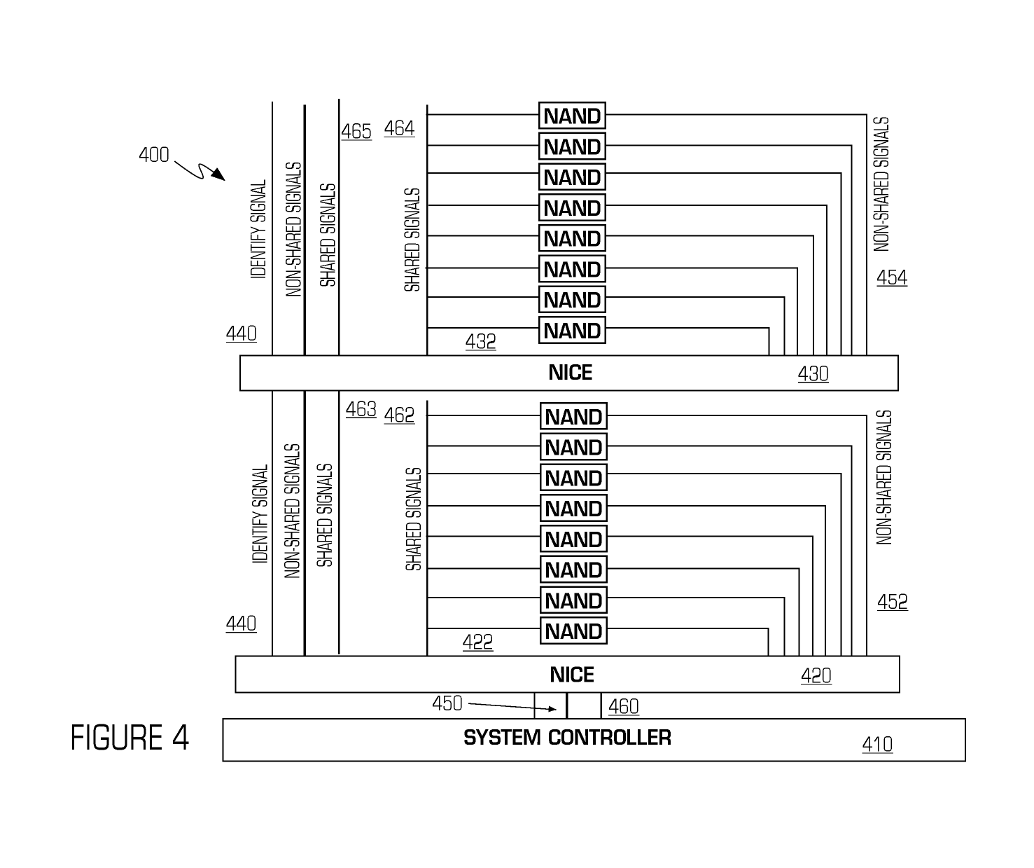

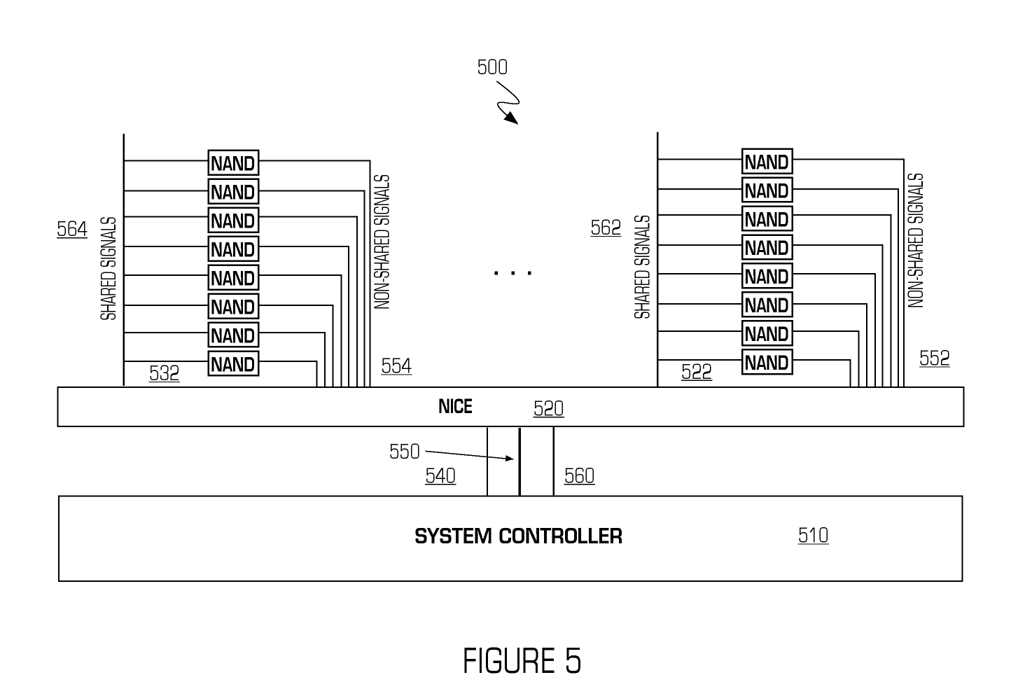

NICE devices are connected to each other in various configurations such as serial mode (see FIG. 1), in parallel mode (see FIG. 2), mixed mode (see FIG. 3), load limited mode (see FIG. 4), and an all in one mode (see FIG. 5). Concepts with the first 3 modes, and the other configurations, are explained below.

In FIGS. 1, 2, and 3, three set of optional signals are communicated between the controller and NICE devices. These signals are also communicated between multiple NICE devices. Regardless of the type of interface, the three types of signals that can be used are:
1. Identify signal that causes the NICE devices to identify themselves with a device number.
2. Non-shared signals that are signals that are directed to individual NAND devices such as chip select or enable to identify a specific NAND device to receive a command or transfer data.
3. Shared signals that are delivered to all NAND devices. In some situations, only the selected NAND device is enabled to receive or transmit. In other situations (such as in a broadcast mode), all NAND devices connected to a NICE device are enabled to receive a signal. Note that when using NICE, shared signals are only delivered to the NANDs connected to the one NICE device.

With reference to FIG. 1, solid state drive 100 is depicted. System controller 110 is coupled to one or more NICE devices such as NICE device 120 and NICE device 130. System controller 110 can connect to additional NICE devices as well. NICE device 120 is connected to a plurality 122 of NAND devices, and NICE device 130 is connected to a plurality 132 of NAND devices. System controller 110 provides Non-shared signals 150 and Shared Signals 160 to NICE device 120 and NICE device 130. In one embodiment, system controller 110 provides Identify signal 140 to NICE device 120, which in turn provides Identify signal 140 to NICE device 130.

NICE device 120 receives Non-shared signals 150 and provides a separate path to each of the plurality 122 of NAND devices, shown as Non-shared signals 152. Similarly, NICE device 130 receives Non-shared signals 150 and provides a separate path to each of the plurality 132 of NAND devices, shown as Non-shared signals 154. When a signal is received over Non-shared signals 150, NICE device 120 and NICE device 130 will forward the signal only to the specific NAND device for which the signal is intended.

NICE device 120 receives Shared signals 160 and provides Shared signals 162 to the plurality 122 of NAND devices. Similarly, NICE device 130 receives Shared signals 160 and provides Shared signals 164 to the plurality 132 of NAND devices. When a signal is received over Shared signals 160, NICE device 120 and NICE device 130 will forward the signal only to the plurality of NAND devices for which the signal is intended. Thus, either Shared signals 162 or Shared signals 164 will forward Shared signals 160, but not both.

With reference to FIG. 2, solid state drive 200 is depicted. System controller 210 is coupled to one or more NICE devices such as NICE device 220 and NICE device 230. System controller 210 can connect to additional NICE devices as well. NICE device 220 is connected to a plurality 222 of NAND devices, and NICE device 230 is connected to a plurality 232 of NAND devices. System controller 210 provides Non-shared signals 250 and Shared Signals 260 to NICE device 220 and NICE device 230. System controller 210 provides Identify signal 240 to NICE device 220, which in turn provides Identify signal 240 to NICE device 230.

NICE device 220 receives Non-shared signals 250 and provides a separate path to each of the plurality 222 of NAND devices, shown as Non-shared signals 252. Similarly, NICE device 230 receives Non-shared signals 250 and provides a separate path to each of the plurality 232 of NAND devices, shown as Non-shared signals 254. When a signal is received over Non-shared signals 250, NICE device 220 and NICE device 230 will forward the signal only to the specific NAND device for which the signal is intended.

NICE device 220 receives Shared signals 260 and provides Shared signals 262 to the plurality 222 of NAND devices. Similarly, NICE device 230 receives Shared signals 260 and provides Shared signals 264 to the plurality 232 of NAND devices. When a signal is received over Shared signals 260, NICE device 220 and NICE device 230 will forward the signal only to the plurality of NAND devices for which the signal is intended. Thus, either Shared signals 262 or Shared signals 264 will forward Shared signals 260, but not both.

With reference to FIG. 3, solid state drive 300 is depicted. System controller 310 is coupled to one or more NICE devices such as NICE device 320 NICE device 330, NICE device 325, and NICE device 335. System controller 310 can connect to additional NICE devices as well. NICE device 320 is connected to a plurality 322 of NAND devices, NICE device 330 is connected to a plurality 332 of NAND devices, NICE device 325 is connected to a plurality 327 of NAND devices, and NICE device 335 is connected to a plurality 337 of NAND devices. System controller 310 provides Non-shared signals 350 and Shared Signals 360 to NICE devices 320, 330, 325, and 335. System controller 310 provides Identify signal 340 to NICE device 320, which in turn provides Identify signal 340 to NICE device 330, which in turn provides Identify signal 340 to NICE device 335, which in turn provides Identify signal 340 to NICE device 325.

NICE device 320 receives Non-shared signals 350 and provides a separate path to each of the plurality 322 of NAND devices, shown as Non-shared signals 352. Similarly, NICE device 330 receives Non-shared signals 350 and provides a separate path to each of the plurality 332 of NAND devices, shown as Non-shared signals 354; NICE device 325 receives Non-shared signals 350 and provides a separate path to each of the plurality 327 of NAND devices, shown as Non-shared signals 356; and NICE device 335 receives Non-shared signals 350 and provides a separate path to each of the plurality 337 of NAND devices, shown as Non-shared signals 358. When a signal is received over Non-shared signals 350, NICE devices 320, 330, 325, and 335 will forward the signal only to the specific NAND device for which the signal is intended.

NICE device 320 receives Shared signals 360 and provides Shared signals 362 to the plurality 322 of NAND devices. Similarly, NICE device 330 receives Shared signals 360 and provides Shared signals 364 to the plurality 332 of NAND devices; NICE device 325 receives Shared signals 360 and provides Shared signals 366 to the plurality 327 of NAND devices; and NICE device 335 receives Shared signals 360 and provides Shared signals 368 to the plurality 337 of NAND devices. When a signal is received over Shared signals 360, NICE devices 320, 330, 325, and 335 will forward the signal only to the plurality of NAND devices for which the signal is intended. Thus, only one of Shared signals 362, 364, 366, and 368 will forward Shared signals 360.

When solid state drive 100 or 200 is powered up, system controller 110 or 210 will use the Identify signal 140 or 240 to assign identification numbers to NICE devices such as NICE devices 120, 130, 220, and 230. In serial or parallel mode, the first NICE device will assign itself ID# 0, which is an example of a NICE device number. Then, it will pass the Identify signal to the next NICE device whom will assign itself ID#8 (assuming the first NICE device has 8 NAND devices that will be identified as NAND devices 0 to 7). Then, the signal is passed on to the next NICE device which will assign itself ID# 16. This process continues until all NICE devices have identified themselves in this manner. Each NICE device number inherently can be used to generate NAND device numbers as well. For example, NICE device ID# 0 can be associated with NAND device numbers 0000, 0001 . . . 0008, etc. In the alternative, NICE device numbers can be pre-assigned to each NICE device. These numbers can be obtained and associated with each NICE device during the initialization process from a ROM or other non-volatile memory.

In the mixed mode configuration of FIG. 3, when solid state drive 300 is powered up, NICE devices such as NICE devices 320, 330, 325, and 335 can go through a “depth first” or “breadth first” identification process, or any combination thereof. “Depth first” implies the first NICE device and those NICE devices directly connected thereto identify themselves first, then the next group of NICE devices connected in parallel to the first NICE device identify themselves, and so on. In FIG. 3, the identification is down the first column (e.g., NICE device 320, then NICE device 325). In parallel mode, identification is done horizontally or across the row first (e.g., NICE device 320, then NICE device 330). The first

NICE device identifies itself, then passes on the signal to the next NICE device horizontally adjacent to it. The process continues to the second column/row, and so on. It is also possible to have some other order of identification that may fit the system more efficiently.

In all embodiments described herein, when the system controller wants to communicate with a specific NAND device, it will send the NAND device number to the first NICE device in the serial mode or to all NICE devices in the parallel mode using non-shared signals. In serial mode, the first NICE device will check the NAND device number against the device numbers for the NAND devices attached to it. If the NAND device is managed by that NICE device, it will enable or select the matching NAND device. Otherwise, it will send the NAND device number to the next NICE device, and so on. In parallel mode, each NICE device will check the NAND device number against its NAND devices, and the NICE device that finds a match will enable or select the matching NAND device.

The selected NAND will receive all the commands from the controller and will execute and respond as long as it is enabled. And, the NICE device with the enabled NAND device continues to manage this interaction. And, in case of serial mode, NICE devices that are on the way to the selected NICE device will pass the information forward because these NICE devices know that they have not been selected, and therefore a NICE device further in the link of NICE devices is selected and needs to receive the information. Similarly, when data or status arrives from a NICE device, the NICE devices between the selected NICE device and the controller will simply forward the information.

The mixed mode configuration of FIG. 3 also follows the order of the NICE devices in ascending order of NICE ID numbers. Alternatively, all NICE devices on the same row receive the command at the same time. Each will check the NAND device number against its NAND device numbers attached to it or attached to those NICE devices that are in its column. A NAND will be selected if the number matches with one of the device numbers attached to the NICE. Or the NICE will pass the information to next row of NICE devices (i.e to the NICE in its column if the number matches with one of them). The information will not be passed to the next row if none of the numbers can be matched.

With reference to FIG. 4, solid state drive 400 is depicted with a limited loading serial connection of NICE devices. System controller 410 is coupled to one or more NICE devices such as NICE device 420 and NICE device 430. System controller 410 can connect to additional NICE devices as well. NICE device 420 is connected to a plurality 422 of NAND devices, and NICE device 430 is connected to a plurality 432 of NAND devices. System controller 410 provides Non-shared signals 450 and Shared Signals 460 to NICE device 420 and NICE device 430. System controller 410 provides Identify signal 440 to NICE device 420, which in turn provides Identify signal 440 to NICE device 430. Notably, Shared signals 463 is provided, which is identical to shared signals 462 but is not loaded by the plurality 422 of NAND devices, and shared signals 465 is provided, which is identical to shared signals 464 but is not loaded by the plurality 432 of NAND devices.

NICE device 420 receives Non-shared signals 450 and provides a separate path to each of the plurality 422 of NAND devices, shown as Non-shared signals 452. Similarly, NICE device 430 receives Non-shared signals 450 and provides a separate path to each of the plurality 432 of NAND devices, shown as Non-shared signals 454. When a signal is received over Non-shared signals 450, NICE device 420 and NICE device 430 will forward the signal only to the specific NAND device for which the signal is intended.

NICE device 420 receives Shared signals 460 and provides Shared signals 462 to the plurality 422 of NAND devices. Similarly, NICE device 430 receives Shared signals 460 and provides Shared signals 464 to the plurality 432 of NAND devices. When a signal is received over Shared signals 460, NICE device 420 and NICE device 430 will forward the signal only to the plurality of NAND devices for which the signal is intended. Thus, either Shared signals 462 or Shared signals 464 will forward Shared signals 460, but not both.

With reference to FIG. 5, solid state drive 500 is depicted with use of only a single NICE device. System controller 510 is coupled to NICE device 520. NICE device 520 is connected to a plurality 522 of NAND devices, a plurality 532 of NAND devices, and possibly to other pluralities of NAND devices.

System controller 510 provides Non-shared signals 550 and Shared Signals 560 to NICE device 520. System controller 510 provides Identify signal 540 to NICE device 520.

NICE device 520 receives Non-shared signals 550 and provides: a separate path to each of the plurality 522 of NAND devices, shown as Non-shared signals 552, a separate path to each of the plurality 532 of NAND devices, shown as Non-shared signals 554, and similar paths of any other plurality of NAND devices. When a signal is received over Non-shared signals 550, NICE device 520 will forward the signal only to the specific NAND device for which the signal is intended.

NICE device 520 receives Shared signals 560 and provides Shared signals 562 to the plurality 522 of NAND devices, Shared signals 564 to the plurality 532 of NAND devices, and a similar Shared signals to any other plurality of NAND devices that is present. When a signal is received over Shared signals 560, NICE device 520 will forward the signal only to the plurality of NAND devices for which the signal is intended. Thus, either Shared signals 562 or Shared signals 564 (or a similar signal) will forward Shared signals 560.

In another aspect of the invention, the number of signals from the controller to the NICE devices can be reduced by removing the non-shared signals that are used to identify the NAND device number, and instead communicate the NAND device number though the shared signals using predefined commands based on a convention between NICE devices and the controller. Since the NICE devices interact with the NAND devices based on the NAND device interface convention, the NICE device will maintain that interface to the NAND devices. However, the interface with the controller or between NICE devices is modified in order to communicate the NAND number implicitly. Specifically, this could be any proprietary interface such as serial link, RF link, or fiber optical link for off board remote connection. The NICE device has local ports/interfaces, which preferably comply with a NAND standard interface in order to connect to commercially available NANDs. The NICE device also preferably has repeating ports, which could be standard compliant or a proprietary interface, for capacity expansion and distance extension. Therefore, the number of signals from the controller to the NICE devices will be reduced, causing a reduction in the pin count of the controller chip.

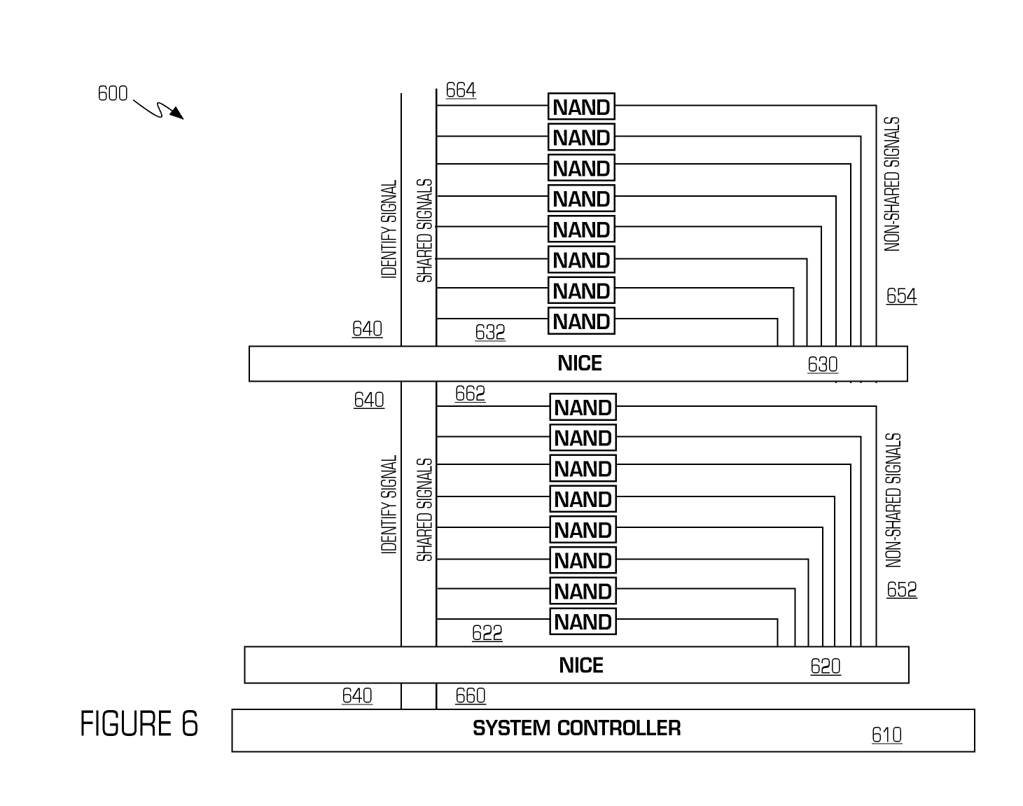

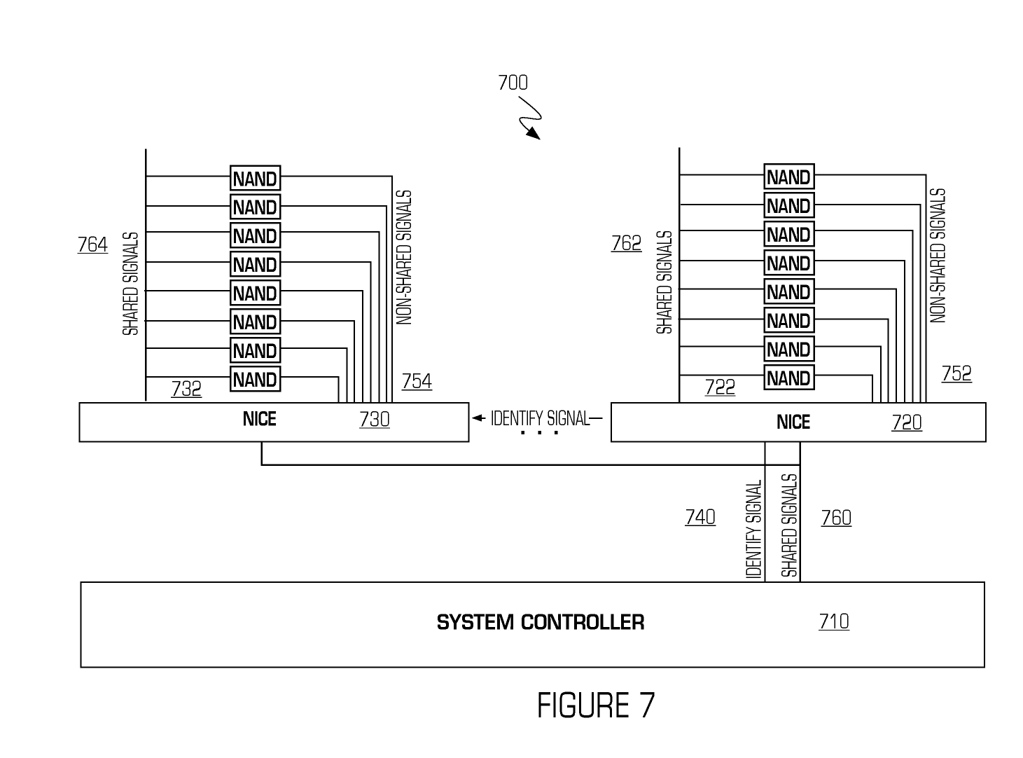

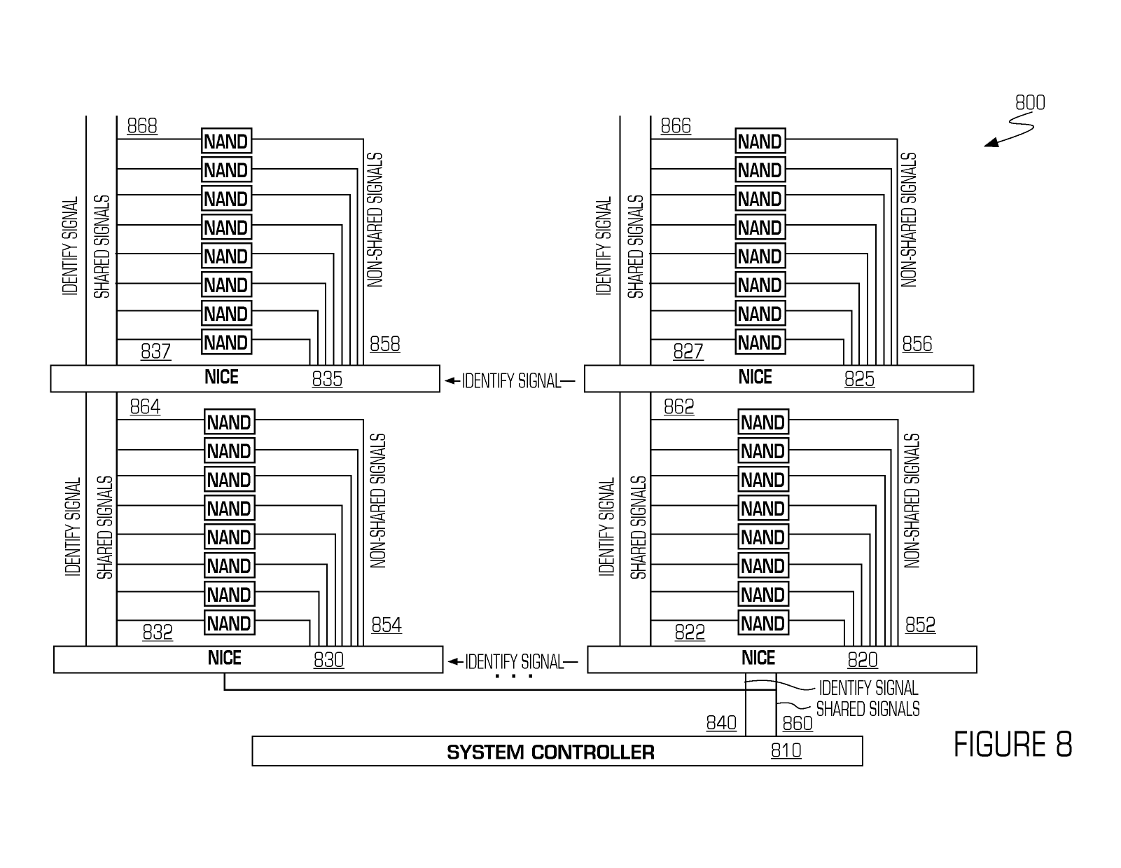

FIG. 6, FIG. 7, and FIG. 8 represent the serial, parallel, and mixed mode configurations, respectively, with non-shared signals removed. With 8 as the limit of the number of NAND devices per bus, the minimum number of signals saved is 8 times the number of NAND buses. This number becomes very significant for a controller with multiple NAND buses, especially when the number of saved power and ground signals are added as well. FIG. 6, FIG. 7, and FIG. 8 operate in a similar manner to FIG. 1, FIG. 2, and FIG. 3, respectively, except that the non-shared signals have been removed. The structures and connections contained therein operate the same as in their corresponding figure.

In yet another aspect of the invention, additional NAND devices may be added as spare NAND devices so that if a NAND device in use fails, a spare NAND device can be substituted for the failed NAND device, hence increasing the reliability and life time of the Solid State Drive. The spare NANDs may be added to one or more of the NICE devices, preferably the last device, or may be added with a dedicated NICE device as spare NICE device.

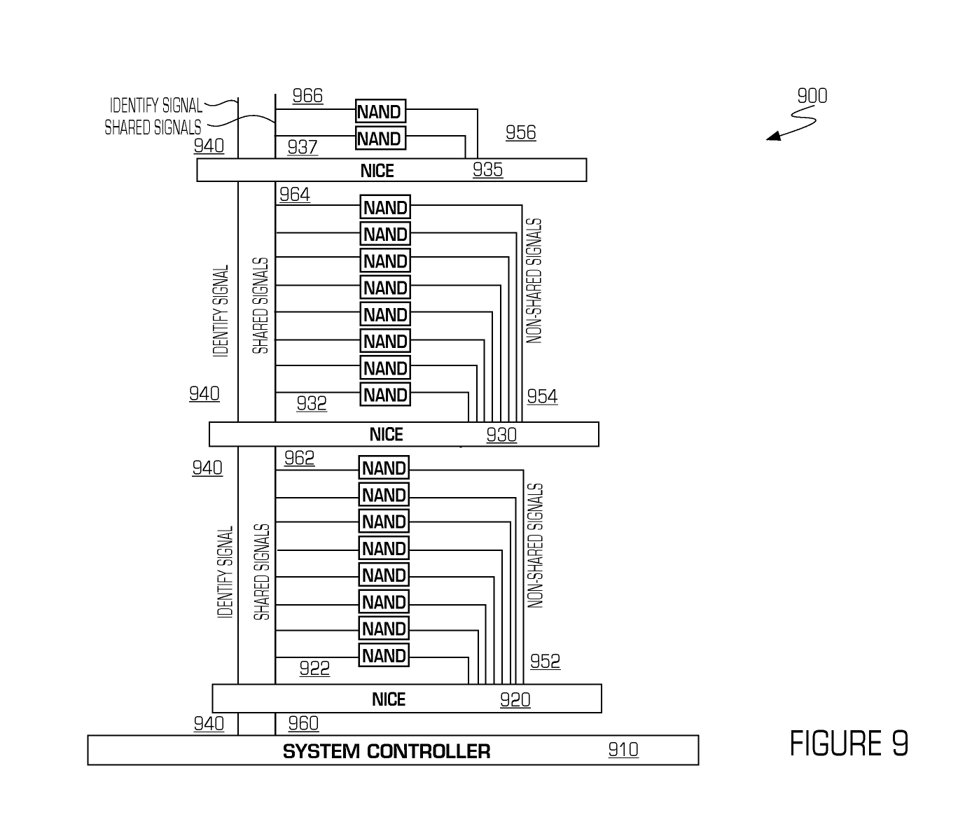

FIG. 9 shows an example of solid state drive 900 with serial mode NICE devices with a spare NICE device 935 with spare NAND devices 937. Other variations are not shown, but the invention contemplates adding spare NAND die to any NICE device or add a spare NICE device to other configurations.

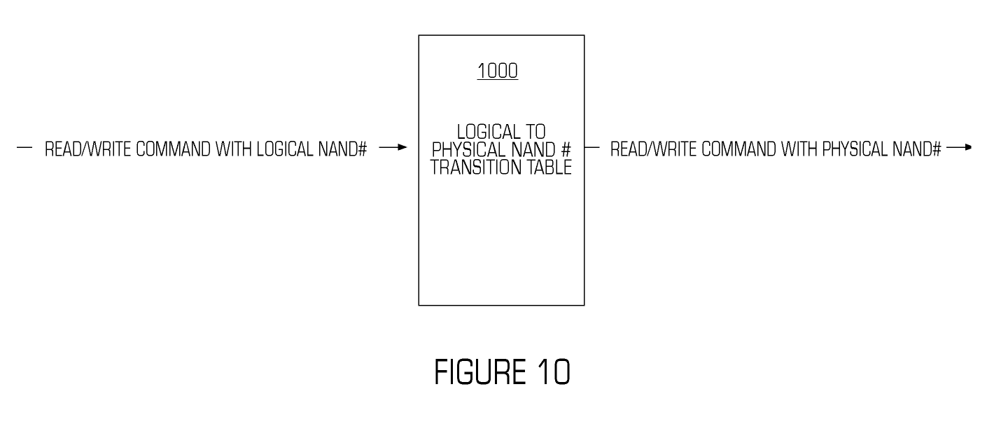

In order to manage the spare NAND devices 937, the system controller 910 preferably keeps a conversion table for mapping logical NAND device numbers to physical NAND device numbers before sending any command to the NICE devices. An example of such conversion can be seen in FIG. 10. When a failed NAND device is detected by the controller, the controller 910 will modify the conversion table to replace the failed NAND device number with a spare NAND device number, as represented by block 1000. Then, all the interaction with the failed NAND device will be redirected to the spare NAND device replacing it. This results in a more robust solid state drive.

It is to be understood that the present invention is not limited to the embodiment(s) described above and illustrated herein, but encompasses any and all variations evident from the above description. For example, references to the present invention herein are not intended to limit the scope of any claim or claim term, but instead merely make reference to one or more features that may be eventually covered by one or more claims.

What is claimed is:

1. A solid state drive, comprising:
a system controller;
one or more extender devices coupled to the system controller, each extender device coupled to a plurality of NAND storage devices, and each NAND storage device comprising a plurality of NAND flash memory cells;
wherein the system controller provides one or more signals to at least one of the extender devices for identification of the extender device.

2. The solid state drive of claim 1, wherein the drive comprises at least two extender devices that are connected in serial.

3. The solid state drive of claim 1, wherein the drive comprises at least two extender devices that are connected in parallel.

4. The solid state drive of claim 1, wherein each extender device provides one or more shared signals to a plurality of NAND storage devices and one or more non-shared signals to each of the plurality of NAND storage devices.

5. The solid state drive of claim 1, wherein the system controller provides one or more signals to a first extender device for identification of the first extender device, and the first extender device provides the one or more signals to a second extender device for identification of the second extender device.

6. The solid state drive of claim 1, wherein each extender device is connected to eight NAND storage devices.

7. The solid state drive of claim 4, the system controller provides the one or more shared signals to one or more of the extender devices.

8. A solid state drive, comprising:
a system controller;
one or more extender devices coupled to the system controller, each extender device coupled to a plurality of NAND storage devices, and each NAND storage device comprising a plurality of NAND flash memory cells; and
a spare extender device coupled to the system controller and coupled to a plurality of spare NAND storage devices, and each spare NAND storage device comprising a plurality of NAND flash memory cells, wherein a spare NAND storage device is utilized in place of a failed NAND storage device;

9. The solid state drive of claim 8, wherein the drive comprises at least two extender devices that are connected in serial.

10. The solid state drive of claim 8, wherein the drive comprises at least two extender devices that are connected in parallel.

11. The solid state drive of claim 8, wherein each extender device provides one or more shared signals to a plurality of NAND storage devices and one or more non-shared signals to each of the plurality of NAND storage devices.

12. The solid state drive of claim 8, wherein the system controller provides one or more signals to a first extender device for identification of the first extender device, and the first extender device provides the one or more signals to a second extender device for identification of the second extender device.

13. The solid state drive of claim 8, wherein each extender device is connected to eight NAND storage devices.

14. The solid state drive of claim 11, the system controller provides the shared signal to one or more of the extender devices.

15. The solid state drive of claim 8, wherein the storage controller provides a mapping from the failed NAND storage device to a spare NAND storage device.

16. A method of initializing a solid state drive comprising a system controller, one or more extender devices coupled to the system controller, each extender device coupled to a plurality of NAND storage devices, and each NAND storage device comprising a plurality of NAND flash memory cells, the method comprising:
performing an extender device initialization routine comprising:
sending one or more signals to the extender device; and
assigning a unique identification number to the extender device; and
repeating the performing step for all extender devices coupled to the system controller.

17. The method of claim 16, wherein the solid state drive comprises at least two extender devices that are connected in serial.

18. The method of claim 16, wherein the solid state drive comprises at least two extender devices that are connected in parallel.

19. The method of claim 16, further comprising:
an extender device providing one or more shared signals to a plurality of NAND storage devices and one or more non-shared signals to each of the plurality of NAND storage devices.

20. The method of claim 16, wherein each extender device is connected to eight NAND storage devices.

21. The method of claim 19, further comprising:
the system controller providing the shared signal to the extender device.
